(19) United States
(12) Patent Application Publication
(10) Pub. No.: US 2026/0052817 A1
(43) Pub. Date: Feb. 19, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: Jongwoo Jin, Yongin-si (KR); YEONHONG KIM, Yongin-si (KR); MYOUNGHWA KIM, Yongin-si (KR); YEON KEON MOON, Yongin-si (KR); JUN HYUNG LIM, Yongin-si (KR)

(21) Appl. No.: 19/188,332

(22) Filed: Apr. 24, 2025

(30) Foreign Application Priority Data
Aug. 16, 2024 (KR) 10-2024-0109717

(51) Int. Cl. H10H 29/32; H01L 25/16; H10D 86/01; H10D 86/40; H10D 86/60; H10H 29/01; H10H 29/41; H10H 29/49

(52) U.S. Cl. CPC H10H 29/32; H01L 25/167; H10D 86/0221; H10D 86/423; H10D 86/60; H10H 29/012; H10H 29/41; H10H 29/49

(57) ABSTRACT

A display device includes a substrate including a display area and a peripheral area surrounding the display area, a first transistor disposed in the peripheral area of the substrate and including a first active layer having a first channel region and a first gate electrode, a first insulating layer disposed on the first transistor, a first shield pattern disposed on the first insulating layer and to which a direct current voltage is applied, a second insulating layer covering the first shield pattern, and a second transistor directly disposed on the second insulating layer and including a second active layer having a second channel region spaced apart from the first shield pattern in a plan view and a second gate electrode.

This application claims priority to Korean Patent Application No. 10-2024-0109717, filed on Aug. 16, 2024, and all the benefits accruing therefrom under 35 U.S.C. § 119, the content of which in its entirety is herein incorporated by reference.

### BACKGROUND

### 1. Field

The invention relates to a display device, a method of manufacturing the display device, and an electronic device including the display device, and more particularly, to a display device, a method of manufacturing the display device, and an electronic device including the display device that provides visual information

### 2. Background of Related Art

Because transistors are manufactured on glass or plastic substrates, transistors are widely used as switching or driving devices in display devices. Meanwhile, display devices have recently become higher quality and higher resolution, and transistors mounted on display devices are becoming more highly integrated.

As a result, a large number of transistors are disposed in a limited area, resulting in transistor overcrowding and coupling between transistors.

### SUMMARY

In an embodiment the invention provides a display device with improved display quality.

In another embodiment the invention provides a method of the display device.

In still yet another embodiment the invention provides an electronic device including the display device.

A display device, according to an embodiment, includes a substrate including a display area and a peripheral area surrounding the display area, a first transistor disposed in the peripheral area of the substrate and including a first active layer having a first channel region and a first gate electrode, a first insulating layer disposed on the first transistor, a first shield pattern disposed on the first insulating layer and to which a direct current voltage is applied, a second insulating layer covering the first shield pattern, and a second transistor directly disposed on the second insulating layer and including a second active layer having a second channel region spaced apart from the first shield pattern in a plan view, and a second gate electrode.

In an embodiment, the first gate electrode and the second gate electrode may be spaced apart from each other in a plan view.

In an embodiment, the display device may further include a conductive pattern disposed below the second transistor, and not overlapping with the first shield pattern in a plan view, and wherein the conductive pattern overlaps with the second channel region of the second transistor in a plan view.

In an embodiment, the conductive pattern may be disposed on a same layer as a source electrode of the first transistor.

In an embodiment, the conductive pattern may be electrically connected to the source electrode or the second gate electrode of the second transistor.

In an embodiment, the display device may further include a second shield pattern disposed to be spaced apart from the second channel region of the second transistor in a plan view, wherein the second shield pattern is disposed on a same layer as the first shield pattern and is spaced apart from the first shield pattern.

In an embodiment, the first shield pattern may overlap the first gate electrode in a plan view.

In an embodiment, the display device may further include a second shield pattern spaced apart from the first shield pattern and including a same material as the first shield pattern, wherein the second shield pattern overlaps the second channel region of the second transistor in a plan view.

In an embodiment, a first direct current voltage may be applied to the first shield pattern, and a second direct current voltage different from the first direct current voltage may be applied to the second shield pattern.

In an embodiment, the second shield pattern may be electrically connected to the first gate electrode and the second gate electrode.

In an embodiment, the first gate electrode and the second gate electrode may overlap in a plan view.

In an embodiment, the display device may further include a third transistor disposed in the display area and including a third active layer disposed on a same layer as the first active layer of the first transistor and a light emitting diode electrically connected to the third transistor.

In an embodiment, each of the first active layer and the second active layer may include an oxide semiconductor.

In an embodiment, a mobility of the second active layer may be greater than a mobility of the first active layer.

In an embodiment, each of the first insulating layer and the second insulating layer may be an organic layer.

In an embodiment, the display device may further include a first hole defined in the first insulating layer and a second hole defined in the second insulating layer, extending from the first hole, and penetrating the second insulating layer, wherein the first hole and the second hole may be filled with an insulating material.

In an embodiment, each of the first active layer and the second active layer may be doped with an n-type material.

A method of manufacturing the display device, according to an embodiment, includes forming a first transistor including a first active layer and a first gate electrode on a substrate, forming a first insulating layer on the first transistor, forming a conductive preliminary shield pattern on the first insulating layer, patterning the preliminary shield pattern to form a first shield pattern that applies a direct current voltage, forming a second insulating layer covering the first shield pattern, and forming a second transistor on the second insulating layer, wherein the second transistor includes a second active layer including a second channel region that does not overlap with the first shield pattern in a plan view and a second gate electrode directly on the second insulating layer.

In an embodiment, the method may further include after forming the second transistor, forming a first hole in the first insulating layer and forming a second hole extending from the first hole in the second insulating layer and filling the first hole and the second hole with an insulating material.

In an embodiment, in forming the first shield pattern by patterning the preliminary shield pattern, a second shield pattern that is spaced apart from the first shield pattern is formed.

An electronic device including the display device, according to an embodiment, includes housing and display device stored in the housing and that display an image, and the display device includes a substrate including a display area and a peripheral area surrounding the display area, a first transistor disposed in the peripheral area of the substrate and including a first active layer having a first channel region, and a first gate electrode, a first insulating layer disposed on the first transistor, a first shield pattern disposed on the first insulating layer and to which a direct current voltage is applied, a second insulating layer covering the first shield pattern, and a second transistor directly disposed on the second insulating layer and including a second active layer having a second channel region spaced apart from the first shield pattern in a plan view, and a second gate electrode.

A display device, according to an embodiment, may include a substrate including a display area and a peripheral area surrounding the display area, a first transistor disposed in the peripheral area of the substrate and including a first active layer having a first channel region and a first gate electrode, a first insulating layer disposed on the first transistor, a first shield pattern disposed on the first insulating layer and to which a direct current voltage is applied, a second insulating layer covering the first shield pattern, and a second transistor directly disposed on the second insulating layer and including a second active layer having a second channel region spaced apart from the first shield pattern in a plan view, and a second gate electrode.

Accordingly, in an embodiment, even when the first transistor and the second transistor are vertically stacked, coupling phenomenon between transistors may be prevented by the first shield pattern. Additionally, in an embodiment, a circuit area of the driving driver and/or pixel circuit may be smaller than when the transistors are arranged horizontally. That is, by vertically stacking transistors, a coupling phenomenon within the display device may be prevented, an area of the peripheral area may be reduced, and a display device with high resolution may be implemented.

### BRIEF DESCRIPTION OF THE DRAWINGS

The accompanying drawings, which are included to provide a further understanding of the invention and which are incorporated in and constitute a part of this specification, illustrate embodiments of the invention together with the description.

FIG. 1 is a perspective view of a display device, according to an embodiment.

FIG. 2 is a plan view showing an embodiment of the display device of FIG. 1, according to an embodiment.

FIG. 3 is a cross-sectional view showing the display device of FIG. 2, according to an embodiment.

FIG. 4 is a plan view showing an upper surface of the display device of FIG. 3, according to an embodiment.

FIG. 5 is a cross-sectional view showing a method of manufacturing the display device of FIG. 3, according to an embodiment.

FIG. 6 is a cross-sectional view showing a method of manufacturing the display device of FIG. 3, according to an embodiment.

FIG. 7 is a cross-sectional view showing a method of manufacturing the display device of FIG. 3, according to an embodiment.

FIG. 8 is a cross-sectional view showing a method of manufacturing the display device of FIG. 3, according to an embodiment.

FIG. 9 is a cross-sectional view showing a method of manufacturing the display device of FIG. 3, according to an embodiment.

FIG. 10 is a cross-sectional view showing a method of manufacturing the display device of FIG. 3, according to an embodiment.

FIG. 11 is a cross-sectional view showing a method of manufacturing the display device of FIG. 3, according to an embodiment.

FIG. 12 is a cross-sectional view showing a method of manufacturing the display device of FIG. 3, according to an embodiment.

FIG. 13 is a cross-sectional view showing a method of manufacturing the display device of FIG. 3, according to an embodiment.

FIG. 14 is a cross-sectional view showing the display device of FIG. 2, according to another embodiment.

FIG. 15 is a plan view showing an upper surface of the display device of FIG. 14, according to an embodiment.

FIG. 16 is a cross-sectional view showing a method of manufacturing the display device of FIG. 15, according to an embodiment.

FIG. 17 is a cross-sectional view showing a method of manufacturing the display device of FIG. 15, according to an embodiment.

FIG. 18 is a cross-sectional view showing a method of manufacturing the display device of FIG. 15, according to an embodiment.

FIG. 19 is a cross-sectional view showing a method of manufacturing the display device of FIG. 15, according to an embodiment.

FIG. 20 is a cross-sectional view showing a method of manufacturing the display device of FIG. 15, according to an embodiment.

FIG. 21 is a cross-sectional view showing the display device of FIG. 2, according to still another embodiment.

FIG. 22 is a cross-sectional view showing a method of manufacturing the display device of FIG. 21, according to still another embodiment.

FIG. 22 is 23 cross-sectional view showing a method of manufacturing the display device of FIG. 21, according to still another embodiment.

FIG. 24 is a cross-sectional view showing a method of manufacturing the display device of FIG. 21, according to still another embodiment.

FIG. 25 is a cross-sectional view showing the display device of FIG. 2, according to still yet another embodiment.

FIG. 26 is a cross-sectional view showing the display device of FIG. 2, according to still yet another embodiment.

FIG. 27 is a cross-sectional view showing the display device of FIG. 2, according to still yet another embodiment.

FIG. 28 is a block-diagram showing an electronic device including the display device of FIG. 1, according to an embodiment.

FIG. 29 is a perspective view showing an embodiment of the electronic device of FIG. 28, according to an embodiment.

### DETAILED DESCRIPTION

Regarding embodiments of the invention disclosed in this specification, specific structural and functional descriptions are merely illustrative for a purpose of explaining the invention, and the invention may be implemented in various forms and should not be construed as limited to the embodiments described in.

Since the invention may be subject to various changes and may have various forms, specific embodiments will be illustrated in the drawings and described in detail in the text. However, this is not intended to limit the invention to a specific form, and should be understood to include all changes, equivalents, and substitutes included in the spirit and technical scope of the invention.

Terms such as first, second, etc. may be used to describe various components, but the components should not be limited by the terms. The above terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments only and is not intended to be limiting of the invention. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, etc. is used to explain a relationship between components shown in the drawings. The terms are relative concepts and are explained based on the direction indicated in the drawings.

Unless otherwise defined, all terms (including technical and scientific terms) used herein have a same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. For example, the second direction D2 may be perpendicular to the first direction D1. In addition, a third direction D3 may be a normal direction of the plane of D1 and D2. That is, the third direction D3 may be perpendicular to the plane formed by the first direction D1 and the second direction D2.

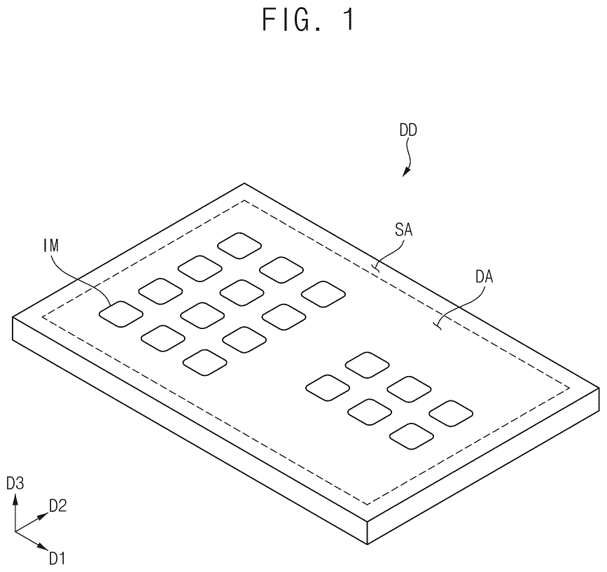

FIG. 1 is a perspective view of a display device, according to an embodiment.

In an embodiment and referring to FIG. 1, a display device DD may include a display area DA and a peripheral area SA, where the display area DA may be surrounded by the peripheral area SA.

In an embodiment, the display area DA may be an area that generates light or may display an image by controlling a transmittance of light provided from an external light source. The peripheral area SA may be an area that does not display an image. However, the invention is not necessarily limited thereto, and at least a portion of the peripheral area SA may display an image.

In an embodiment, the display area DA may display a plurality of images IM, where users may receive information from the display device DD through the plurality of images IM.

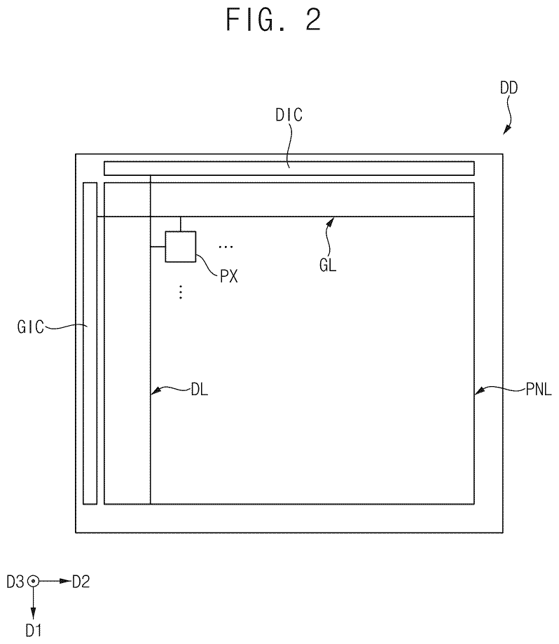

FIG. 2 is a plan view showing an embodiment of the display device of FIG. 1. In an embodiment and referring to FIGS. 1 and 2, the display device DD may include a display panel PNL, a data driver DIC, data lines DL, a gate driver GIC, and gate lines GL.

In an embodiment, a plurality of pixels PX may be disposed on the display panel PNL and may be repeatedly disposed in a matrix form in the first direction D1 and/or the second direction D2 in a plan view. The display device DD may transmit information to a user by light emitted by the pixels PX disposed on the display panel PNL.

In an embodiment, the data driver DIC may be disposed in the peripheral area SA of the display device DD. Specifically, as shown in FIG. 2, the data driver DIC may be disposed to be spaced apart from the display panel PNL in a direction opposite to the first direction D1. The data driver DIC may supply a data signal to the data lines DL in response to a data control signal. The data lines DL may extend in the first direction D1 and may be disposed to be spaced apart from each other in the second direction D2.

In an embodiment, the gate driver GIC may be disposed in the peripheral area SA of the display device DD. Specifically, as shown in FIG. 2, the gate driver GIC may be disposed to be spaced apart from the display panel PNL in a direction opposite to the second direction D2. The gate driver GIC may supply a gate signal to the gate lines GL in response to a gate control signal. The gate lines GL may extend in the second direction D2 and be disposed to be spaced apart from each other in the first direction D1.

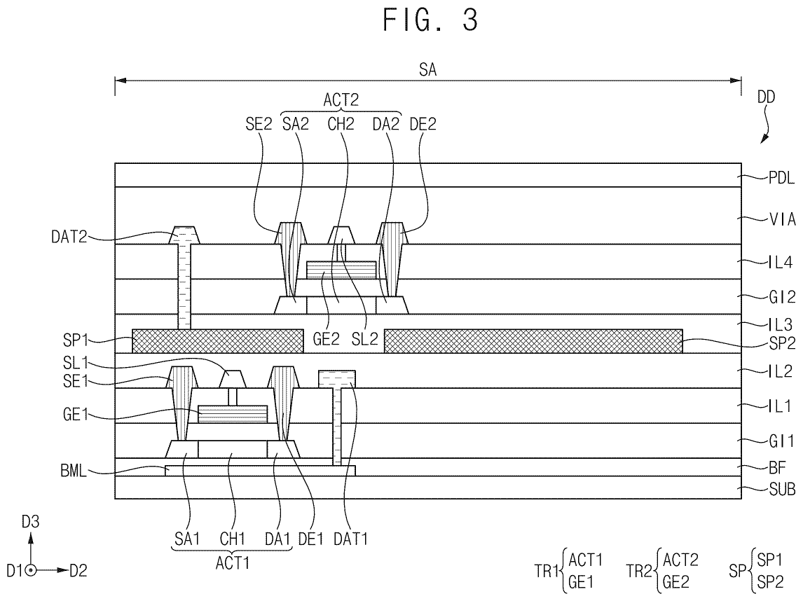

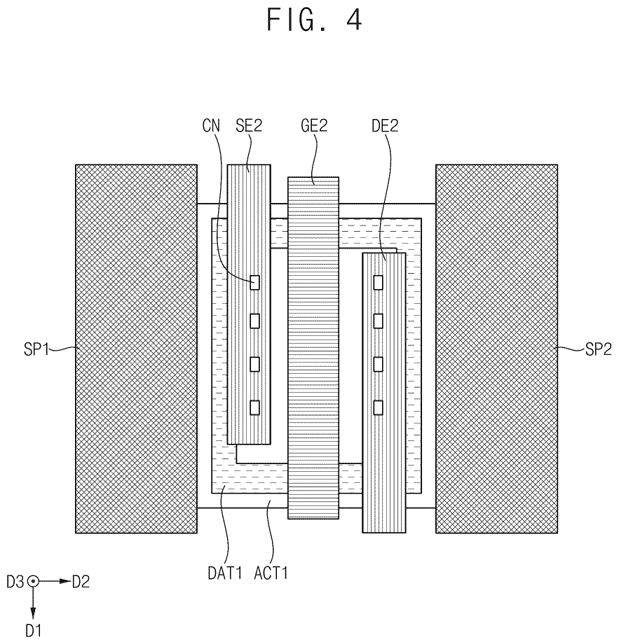

FIG. 3 is a cross-sectional view showing an embodiment of the display device of FIG. 2. FIG. 4 is a plan view showing an embodiment of an upper surface of the display device of FIG. 3. Specifically, FIG. 3 illustrates a cross-sectional view of the peripheral area SA of the display device DD, according to an embodiment.

In an embodiment and referring to FIGS. 1, 2, 3, and 4, the display device DD may include a substrate SUB, a light shielding layer BML, a buffer layer BF, a first transistor TR1, first and second gate insulating layers GI1, GI2, respectively, first, second, third, and fourth insulating layers IL1, IL2, IL3, and IL4, respectively, a first conductive pattern DAT1, a shield pattern SP, a second transistor TR2, a second conductive pattern DAT2, a via layer VIA, and a pixel defining layer PDL.

In an embodiment, the first transistor TR1 may include a first active layer ACT1, a first gate electrode GE1, a first source electrode SE1, and a first drain electrode DE1. The second transistor TR2 may include a second active layer ACT2, a second gate electrode GE2, a second source electrode SE2, and a second drain electrode DE2.

In an embodiment, the substrate SUB may include a glass substrate, a metal substrate, a plastic substrate, etc. However, the invention is not necessarily limited thereto, and in other embodiments, the substrate SUB may be an inorganic layer, an organic layer, or a composite material layer.

In an embodiment, the light shielding layer BML may be disposed on the substrate and may block light coming from the substrate SUB, thereby preventing voltage shift of the first active layer ACT1 of the first transistor TR1 so that the first transistor TR1 may operate normally. For example, the light shielding layer BML may include at least one of gold (Au), silver (Ag), aluminum (Al), molybdenum (Mo), chromium (Cr), titanium (Ti), nickel (Ni), neodymium (Nd), copper (Cu), and platinum (Pt). These may be used alone or in combination with each other. However, the invention is not necessarily limited thereto.

In an embodiment, the buffer layer BF may be disposed on the substrate SUB. Specifically, the buffer layer BF may cover the light shielding layer BM L and may be disposed on the substrate SUB, where the buffer layer BF may prevent impurities such as oxygen, moisture, etc. from penetrating into an upper portion of the substrate SUB through the substrate SUB. The buffer layer BF may include an inorganic insulating material.

In an embodiment, the first active layer ACT1 may be disposed on the buffer layer BF, where the first active layer ACT1 may define a first source region SA1, a first drain region DA1, and a first channel region CH1 located between the first source region SA1 and the first drain region DA1. The first active layer ACT1 may include an oxide semiconductor, a silicon semiconductor, an organic semiconductor, etc. The first active layer ACT1 may have a multilayer structure in which two layers having different compositions are stacked.

For example, in an embodiment, the oxide semiconductor may include at least one of an IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, and ITZO (InSnZnO)-based oxide semiconductor material, indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, crystalline silicon, etc. These may be used alone or in combination with each other. However, the invention is not necessarily limited thereto.

In an embodiment, when an indium content included in the first active layer ACT1 is divided by a gallium content included in the first active layer ACT1, a value, which refers to a numerical ratio of indium to gallium, of about 2 or greater may be derived. When an indium content included in the first active layer ACT1 is divided by a gallium content included in the first active layer ACT1, a value, which refers to a numerical ratio of indium to gallium, of about 3 or greater may be derived.

In an embodiment, the first gate insulating layer GI1 may be disposed on the buffer layer BF. Specifically, the first gate insulating layer GI1 may cover the first active layer ACT1 and may be disposed on the buffer layer BF. For example, the first gate insulating layer GI1 may be formed entirely over the display area DA and the peripheral area SA. The first gate insulating layer GI1 may include an inorganic insulating material.

In an embodiment, the first gate electrode GE1 may be disposed on the first gate insulating layer GI1 and may overlap at least a portion of the first channel region CH1 of the first active layer ACT1. The first gate electrode GE1 may include a conductive material such as a metal, an alloy, a conductive metal nitride, a conductive metal oxide, or a transparent conductive material. The conductive material that may be used for the first gate electrode GE1 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy including aluminum, an alloy including silver, an alloy including copper, an alloy including molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. In another embodiment, the first gate electrode GE1 may have a single-layer structure or a multi-layer structure including a plurality of conductive layers.

In an embodiment, the first insulating layer IL1 may be disposed on the first gate electrode GE1. Specifically, the first insulating layer IL1 may cover the first gate electrode GE1 and may be disposed on the first gate insulating layer GI1. The first insulating layer IL1 may include an inorganic insulating material. For example, the first insulating layer IL1 may include silicon nitride (SiₓNₓ).

In an embodiment, the first source electrode SE1 and the first drain electrode DE1 may be disposed on the first insulating layer IL1, where each of the first source electrode SE1 and the first drain electrode DE1 may be connected to the first active layer ACT1. For example, the first source electrode SE1 may be in contact with the first source region SA1 of the first active layer ACT1, and the first drain electrode DE1 may be in contact with the first drain region DA1 of the first active layer ACT1. Each of the first source electrode SE1 and the first drain electrode DE1 may include a conductive material.

In an embodiment, the first sensing line SL1 may be disposed in a same layer as the first source electrode SE1 and the first drain electrode DE1 and may apply the gate signal applied from the gate driver GIC to the first gate electrode GE1. The first sensing line SL1 may include a same material as the first source electrode SE1 and the first drain electrode DE1.

In an embodiment, the first conductive pattern DAT1 may be disposed in a same layer as the first source electrode SE1. However, the invention is not necessarily limited thereto. The first conductive pattern DAT1 may be disposed in an arbitrary layer below the second transistor TR2. The first conductive pattern DAT1 may not overlap with the shield pattern SP in a plan view.

In an embodiment, the first conductive pattern DAT1 may be electrically connected to the light shielding layer BML. Specifically, the first conductive pattern DAT1 may be electrically connected to the light shielding layer BML by penetrating the first insulating layer IL1, the first gate insulating layer GI1, and the buffer layer BF.

In an embodiment, the second insulating layer IL2 may be disposed on the first insulating layer IL1. Specifically, the second insulating layer IL2 may be disposed on the first insulating layer IL1 and may cover the first source electrode SE1 and the second drain electrode DE2. For example, the second insulating layer IL2 may include a same material as the first insulating layer IL1.

In an embodiment, the shield pattern SP may be disposed on the second insulating layer IL2, where the shield pattern SP may be disposed between the first transistor TR1 and the second transistor TR2 to prevent a coupling phenomenon from occurring between the first transistor TR1 and the second transistor TR2. For example, the shield pattern SP may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy including aluminum, an alloy including silver, an alloy including copper, an alloy including molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. However, the invention is not necessarily limited thereto.

In an embodiment, a direct current voltage may be applied to the shield pattern SP. That is, the shield pattern SP may be a conductive material that applies a constant voltage. For example, the direct current voltage applied to the shield pattern SP may be a pixel driving voltage, a ground voltage, or a gate driving voltage. However, the invention is not necessarily limited thereto.

In an embodiment, since the direct current voltage is applied to the shield pattern SP, the shield pattern SP may reduce or prevent an occurrence of an electromagnetic induction phenomenon due to a change in a surrounding voltage. Accordingly, a voltage applied to the first gate electrode GE1 of the first transistor TR1 may be prevented from causing a coupling phenomenon to the second transistor TR2.

In an embodiment, the shield pattern SP may include a first shield pattern SP1 and a second shield pattern SP2, where the first shield pattern SP1 may overlap with the first gate electrode GE1 of the first transistor TR1 in a plan view, and the second shield pattern SP2 may not overlap with the first gate electrode GE1 in a plan view.

For example, in an embodiment, the first shield pattern SP1 and the second shield pattern SP2 may be disposed to be spaced apart from each other in a plan view. The first shield pattern SP1 and the second shield pattern SP2 may be disposed on a same layer and spaced apart from each other. That is, the first shield pattern SP1 and the second shield pattern SP2 may not be electrically connected to each other.

In an embodiment, a first direct current voltage may be applied to the first shield pattern SP1, and a second direct current voltage different from the first direct current voltage may be applied to the second shield pattern SP2. However, the invention is not necessarily limited thereto and in another embodiment the first direct current voltage may be applied to the first shield pattern SP1, and an alternating current voltage may be applied to the second shield pattern SP2.

In an embodiment, the shield pattern SP may overlap with the first gate electrode GE1 of the first transistor TR1 in a plan view. For example, a planar area of the shield pattern SP may be greater than a planar area of the first gate electrode GE1. Specifically, the first shield pattern SP1 may overlap with the first gate electrode GE1 of the first transistor TR1 in a plan view, and the second shield pattern SP2 may not overlap with the first gate electrode GE1 of the first transistor TR1 in a plan view. Since the shield pattern SP and the first gate electrode GE1 overlap in a plan view, a coupling phenomenon may be prevented from occurring between the electrical signal of the first gate electrode GE1 and the second active layer ACT2 of the second transistor TR2.

In an embodiment, the shield pattern SP may form a capacitor with the first source electrode SE1 and/or the first drain electrode DE1. That is, the shield pattern SP, which is a conductor, the first source electrode SE1, and the first drain electrode DE1 may be adjacently disposed to form a capacitor.

In an embodiment, the third insulating layer IL3 may be disposed on the second insulating layer IL2. Specifically, the third insulating layer IL3 may be disposed on the second insulating layer IL2 and may cover the shield pattern SP and may include a same material as the first insulating layer IL1.

In an embodiment, the second active layer ACT2 may be disposed on the third insulating layer IL3, where the second active layer ACT2 may define a second source region SA2, a second drain region DA2, and a second channel region CH2 located between the second source region SA2 and the second drain region DA2. The second active layer ACT2 may include a same material as the first active layer ACT1. The second active layer ACT2 may have a structure in which two layers having different compositions are laminated.

In an embodiment, the second active layer ACT2 may be directly disposed on the third insulating layer IL3. That is, no other conductor may be disposed between the shield pattern SP and the second active layer ACT2 in a cross-sectional view. Accordingly, a conductor closest to the second active layer ACT2 under the second active layer ACT2 may be the shield pattern SP. The second active layer ACT2 may include a same material as the first active layer ACT1. However, the invention is not necessarily limited thereto.

In an embodiment, a mobility of the second active layer ACT2 may be greater than a mobility of the first active layer ACT1. For example, the first active layer ACT1 may include IGZO, and the second active layer ACT2 may include a material having a mobility greater than IGZO.

In an embodiment, a mobility of carriers in the first active layer ACT1 and/or the second active layer ACT2 may be greater than or equal to about 20 cm²/Vs. Preferably, a mobility of carriers in the first active layer ACT1 and/or the second active layer ACT2 may be greater than or equal to about 20 cm²/Vs and less than or equal to about 40 cm²/Vs.

In an embodiment, the second channel region CH2 of the second active layer ACT2 may not overlap with the shield pattern SP in a plan view. That is, the second channel region CH2 may not overlap with the first shield pattern SP1 that applies the first direct current voltage and the second shield pattern SP2 that is spaced apart from the first shield pattern SP1 in a plan view.

In an embodiment, the second channel region CH2 of the second transistor TR2 may overlap with the first conductive pattern DAT1 in a plan view. That is, the second channel region CH2 may not overlap with the shield pattern SP in a plan view, but may overlap with the first conductive pattern DAT1 in a plan view.

In an embodiment, each of the first transistor TR1 and the second transistor TR2 may be an NMOS transistor. That is, the first source region SA1 and the first drain region DA1 of the first transistor TR1 may be doped with an N-type material and the second source region SA2 and the second drain region DA2 of the second transistor TR2 may be doped with an N-type material. When the first transistor TR1 and the second transistor TR2 are NM OS transistors, if the first transistor TR1 and the second transistor TR2 are vertically stacked, an area occupied by the first transistor TR1 and the second transistor TR2 in the display device DD may be reduced in a plan view. Accordingly, an area of the peripheral region SA of the display device DD may be reduced in a plan view, and an area of the display area DA may be relatively increased in a plan view.

In an embodiment, the second gate insulating layer GI2 may be disposed on the third insulating layer IL3. Specifically, the second gate insulating layer GI2 may be disposed on the third insulating layer IL3 and may cover the second active layer ACT2. The second gate insulating layer GI2 may be formed entirely over the display area DA and the peripheral area SA. The second gate insulating layer GI2 may include a same material as the first gate insulating layer GI1.

In an embodiment, the second gate electrode GE2 may be disposed on the second gate insulating layer GI2 and may overlap at least a portion of the second channel region CH2 of the second active layer ACT2. The second gate electrode GE2 may include a same material as the first gate electrode GE1.

In an embodiment, the second gate electrode GE2 may be spaced apart from the first gate electrode GE1 in a plan view. That is, the second gate electrode GE2 may not overlap with the first gate electrode GE1 in a plan view. Accordingly, the first transistor TR1 and the second transistor TR2 may not overlap in a plan view, as shown in FIG. 3.

In an embodiment, the first conductive pattern DAT1 may be electrically connected to the second active layer ACT2 or the second gate electrode GE2 of the second transistor TR2. Specifically, the first conductive pattern DAT1 may be electrically connected to the second source electrode SE2 or the second gate electrode GE2 of the second transistor TR2. Since the first conductive pattern DAT1 is electrically connected to the second source electrode SE2 or the second gate electrode GE2 of the second transistor TR2, a voltage shift phenomenon of the second channel region CH2 of the second active layer ACT2 may be prevented or reduced.

In an embodiment, the fourth insulating layer IL4 may be disposed on the second gate insulating layer GI2. Specifically, the fourth insulating layer IL4 may be disposed on the second gate insulating layer GI2 and may cover the second gate electrode GE2. The fourth insulating layer IL4 may include a same material as the first insulating layer IL1.

In an embodiment, the second source electrode SE2 and the second drain electrode DE2 may be disposed on the fourth insulating layer IL4. Each of the second source electrode SE2 and the second drain electrode DE2 may be connected to the second active layer ACT2. For example, the second source electrode SE2 may contact the second source region SA2 of the second active layer ACT2 through a connection electrode CN, and the second drain electrode DE2 may contact the second drain region DA2 of the second active layer ACT2 through the connection electrode CN. Each of the second source electrode SE2 and the second drain electrode DE2 may include a conductive material.

In an embodiment, the second sensing line SL2 may be disposed on a same layer as the second source electrode SE2 and the second drain electrode DE2, where the second sensing line SL2 may apply the gate signal applied from the gate driver GIC to the second gate electrode GE2. The second sensing line SL2 may include a same material as the first sensing line SL1.

In an embodiment, the second conductive pattern DAT2 may be disposed on a same layer as the second source electrode SE2. For example, the second conductive pattern DAT2 may penetrate the fourth insulating layer IL4, the second gate insulating layer GI2, and the third insulating layer IL3 and may be connected to one of the shield patterns SP. For example, the second conductive pattern DAT2 may be electrically connected to the first shield pattern SP1. The second conductive pattern DAT2 may apply the first direct current voltage to the first shield pattern SP1.

In an embodiment, the via layer VIA may be disposed on the fourth insulating layer IL4. Specifically, the via layer VIA may be disposed on the fourth insulating layer IL4 and may cover the second source electrode SE2 and the second drain electrode DE2. The via layer VIA may be a planarization layer. The via layer VIA1 may be formed only in a portion of the display area DA and the peripheral area SA. For example, the via layer VIA may include an organic insulating material.

In an embodiment, the pixel defining layer PDL may be disposed on the via layer VIA. The pixel defining layer PDL may also be disposed in a portion of the peripheral area SA and may include an inorganic insulating material or an organic insulating material.

As a result, in an embodiment, by applying a direct current voltage to the shield pattern SP and since the shield pattern SP does not overlap with the second channel area CH2 of the second transistor TR2, a coupling phenomenon between transistors may be prevented even when the first transistor TR1 and the second transistor TR2 are vertically stacked. Accordingly, an area of the driving driver and/or the pixel circuit may be reduced in a plan view compared to a case where transistors are horizontally disposed. That is, by vertically stacking the transistors, a coupling phenomenon in the display device DD may be prevented, an area of the peripheral area may be reduced, and a display device having a high resolution may be implemented.

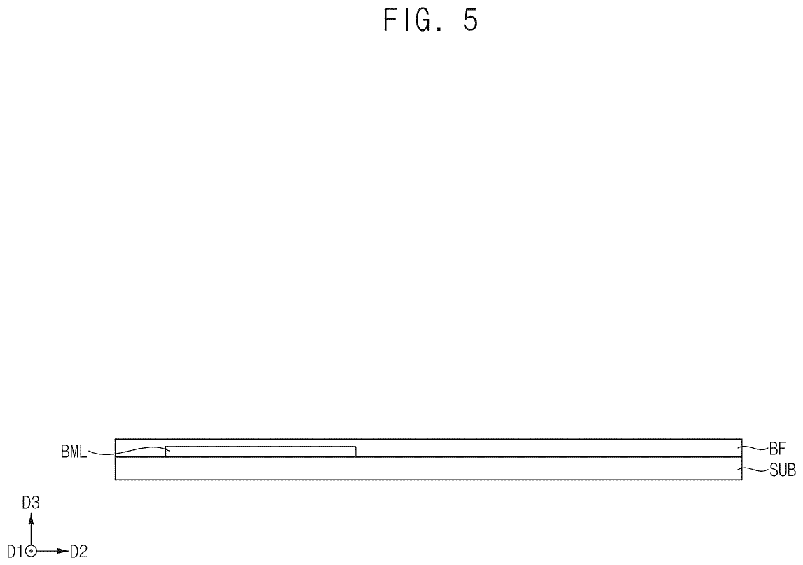

FIGS. 5, 6, 7, 8, 9, 10, 11, 12, and 13 are cross-sectional views showing a method of manufacturing the display device of FIG. 3, according to an embodiment.

In an embodiment and referring to FIG. 5, a light shielding layer BML may be formed on the substrate SUB. Additionally the buffer layer BF covering the light shielding layer BML may be formed on the substrate SUB.

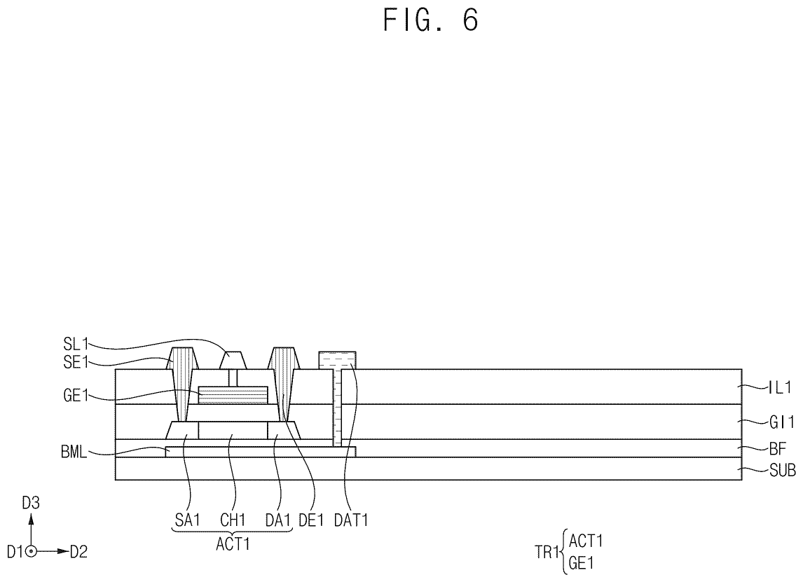

In an embodiment and referring further to FIG. 6, the first transistor TR1 including the first active layer ACT1 may be formed on the buffer layer BF and the first channel region CH1 of the first active layer ACT1 may be formed to overlap with the light shielding layer BM L in a plan view.

In an embodiment, in forming the first source electrode SE1 and the first drain electrode DE1 of the first transistor TR1, the first sensing line SL1 and the first conductive pattern DAT1 may be formed. That is, the first source electrode SE1, the first drain electrode DE1, the first sensing line SL1, and the first conductive pattern DAT1 may be formed on a same layer. However, the invention is not necessarily limited thereto, and in another embodiment, the first conductive pattern DAT1 may be formed on a different layer from the first source electrode SE1.

In an embodiment, the first conductive pattern DAT1 may be formed by penetrating the first insulating layer IL1, the first gate insulating layer GI1, and the buffer layer BF and contacting the light shielding layer BML. That is, the first conductive pattern DAT1 may be formed while being electrically connected to the light shielding layer BM L.

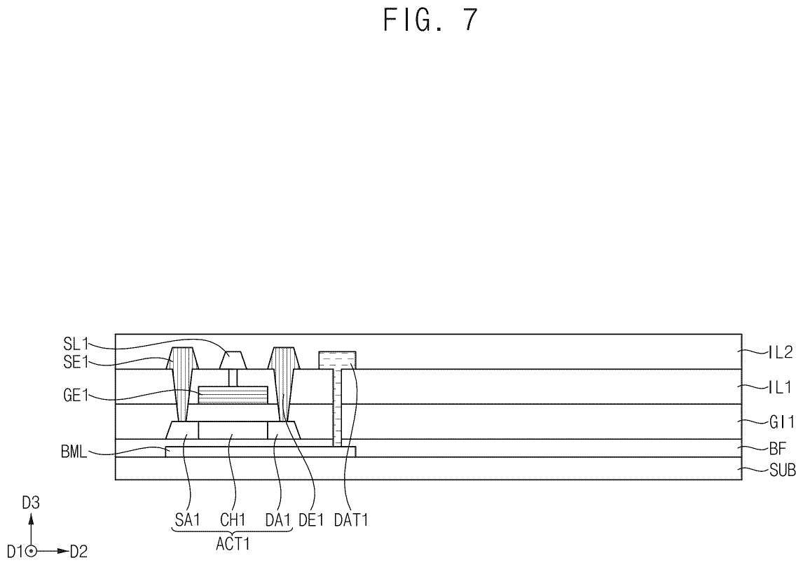

In an embodiment and referring further to FIG. 7, the second insulating layer IL2 may be formed on the first insulating layer IL1, where the second insulating layer IL2 may be formed to cover the first source electrode SE1 and the second drain electrode DE2. For example, the second insulating layer IL2 may be formed through a method such as Chemical Vapor Deposition (CVD), Physical Vapor Deposition (PVD), etc.

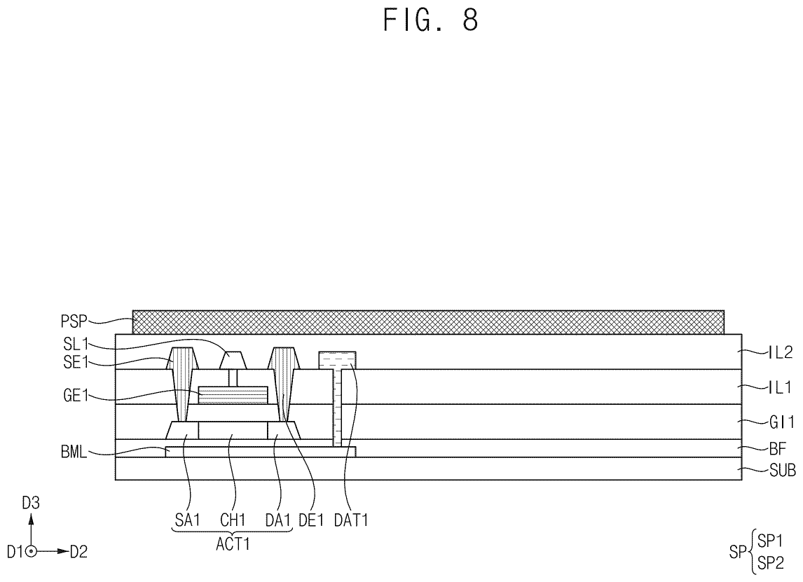

In an embodiment and referring further to FIG. 8, a preliminary shield pattern PSP may be formed on the second insulating layer IL2, where the preliminary shield pattern PSP may be applied to an entire area of the second insulating layer IL2 with a constant thickness. The preliminary shield pattern PSP may include a same material as the shield pattern (e.g., the shield pattern SP of FIG. 3).

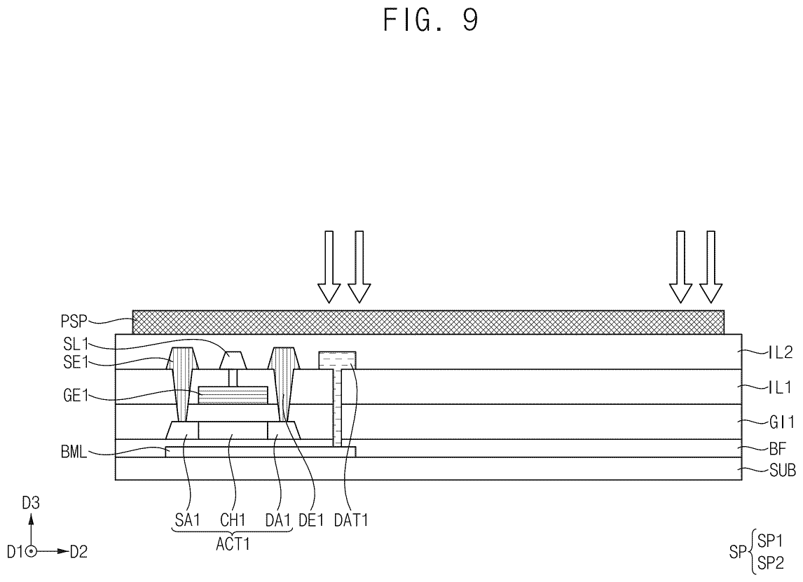

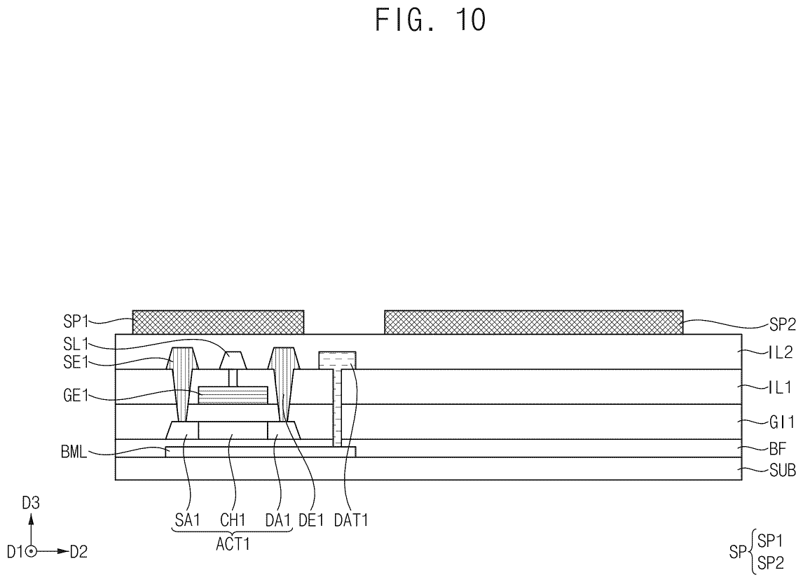

In an embodiment and referring further to FIGS. 9 and 10, the preliminary shield pattern PSP may be patterned to form a shield pattern SP. As shown in FIG. 10, the preliminary shield pattern PSP may be patterned to form the first shield pattern SP1 and the second shield pattern SP2, where the first shield pattern SP1 may be formed to overlap with the first gate electrode GE1 of the first transistor TR1 in a plan view, and the second shield pattern SP2 may be formed to not overlap with the first gate electrode GE1.

In an embodiment and referring to FIG. 10, the first shield pattern SP1 and the second shield pattern SP2 are shown as being spaced apart, but the invention is not necessarily limited thereto. In another embodiment, the first shield pattern SP1 and the second shield pattern SP2 may be electrically connected.

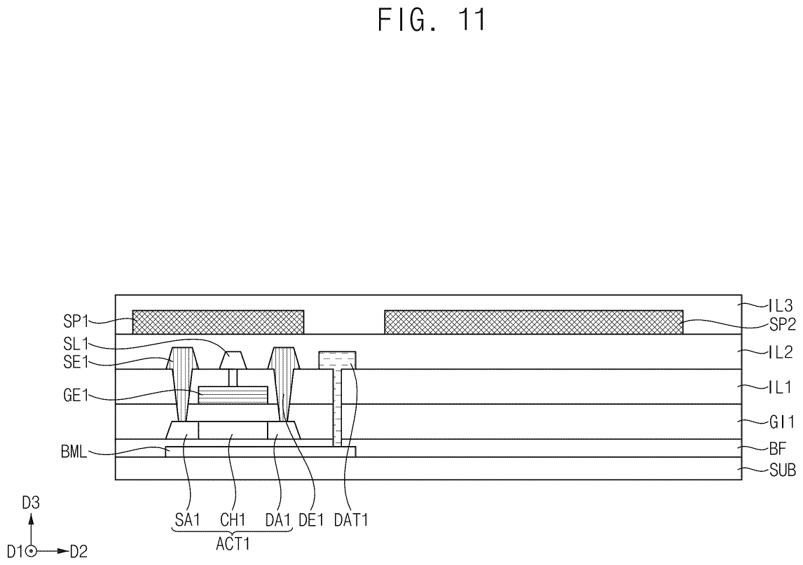

In an embodiment and referring further to FIG. 11, the third insulating layer IL3 may be formed on the second insulating layer IL2, where the third insulating layer IL3 may be formed while covering the shield pattern SP. For example, the third insulating layer IL3 may be formed through a same method as the second insulating layer.

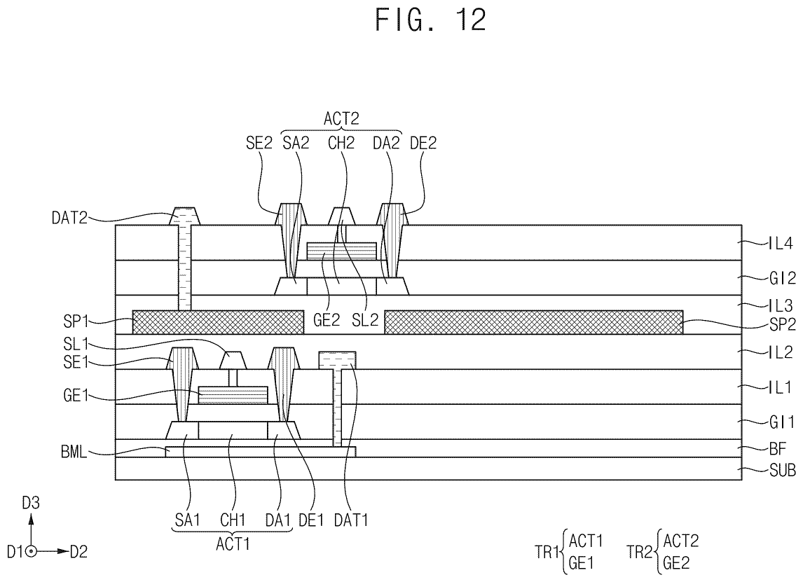

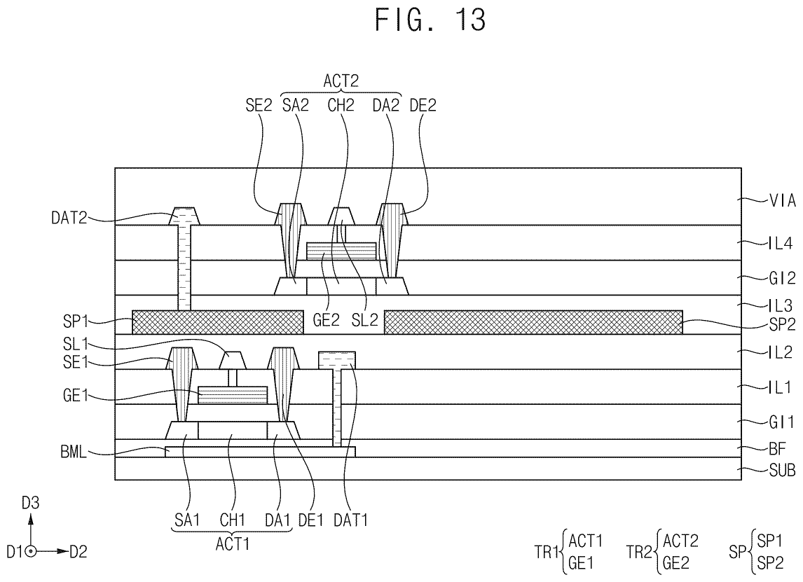

In an embodiment and referring further to FIG. 12 and FIG. 13, the second transistor TR2 including the second active layer ACT2 may be formed on the third insulating layer IL3. The second channel region CH2 of the second active layer ACT2 of the second transistor TR2 may be formed so as not to overlap with the shield pattern SP in a plan view. In addition, the second channel region CH2 of the second active layer ACT2 may be formed so as to overlap with the first conductive pattern DAT1 in a plan view.

In an embodiment, the second active layer ACT2 of the second transistor TR2 may be formed directly on the third insulating layer IL3. That is, as the third insulating layer IL3 covers the shield pattern SP, and the second active layer ACT2 is formed directly on the third insulating layer IL3, no other conductor may be formed between the second active layer ACT2 and the shield pattern SP.

In an embodiment, the second conductive pattern DAT2 may be formed on a same layer as the second source electrode SE2 of the second transistor TR2. The second conductive pattern DAT2 may be formed on a same layer as the second source electrode SE2 by penetrating the fourth insulating layer IL4, the second gate insulating layer GI2, and the third insulating layer IL3. For example, the second challenge pattern DAT2 may be formed and electrically connected to the first shield pattern SP1.

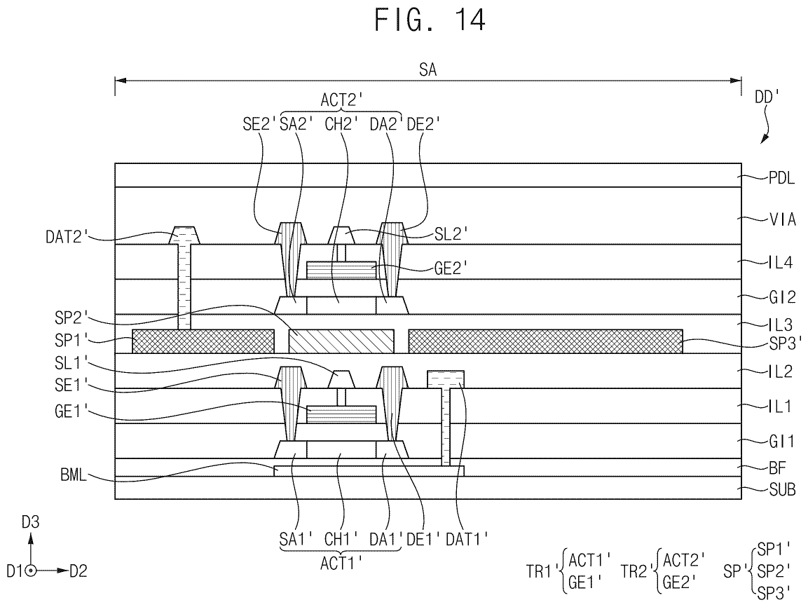

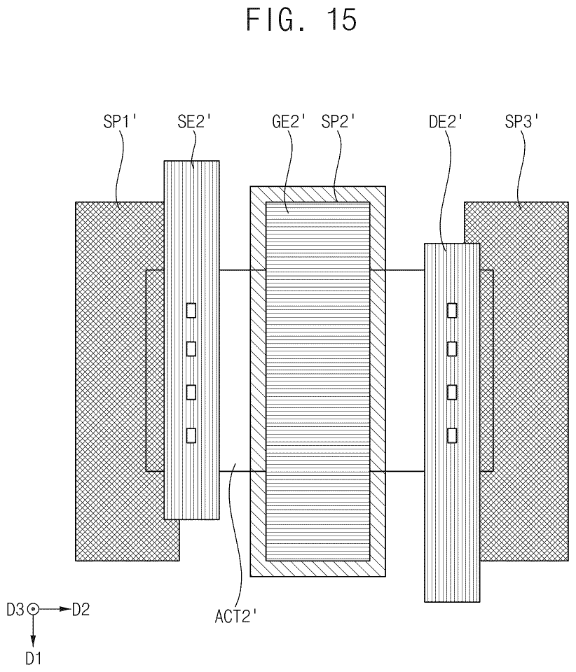

FIG. 14 is a cross-sectional view showing another embodiment of the display device of FIG. 2. FIG. 15 is a plan view showing an embodiment of an upper surface of the display device of FIG. 14. Specifically, FIG. 14 may be substantially same as the configuration described in FIG. 3 except for an arrangement of the configurations. Therefore, overlapping content may be omitted or simplified.

In an embodiment and referring to FIGS. 2, 3, 14, and 15, the second insulating layer IL2 of the display device DD′ may be disposed on the first insulating layer IL1 and may cover the first source electrode SE1′ and the first drain electrode DE1′ of the first transistor TR1′.

In an embodiment, the shield pattern SP′ may be disposed on the second insulating layer IL2. For example, the shield pattern SP′ may include a first shield pattern SP1′, a second shield pattern SP2′, and a third shield pattern SP3′, where each of the first shield pattern SP1′, the second shield pattern SP2′, and the third shield pattern SP3′ may be disposed to be spaced apart from each other. That is, the first shield pattern SP1′, the second shield pattern SP2′, and the third shield pattern SP3′ may not be electrically connected to each other. However, the invention is not necessarily limited thereto, and in another embodiment, the first shield pattern SP1′ and the third shield pattern SP3′ may be electrically connected to each other, and the second shield pattern SP2′ may be independently spaced apart.

In an embodiment, the first direct current voltage may be applied to the first shield pattern SP1′, and the second direct current voltage, which is different from the first direct current voltage, may be applied to the second shield pattern SP2′. That is, different direct current voltages may be applied to the first shield pattern SP1′ and the second shield pattern SP2′.

In an embodiment, the first direct current voltage may be applied to the first shield pattern SP1′ and the third shield pattern SP3′. That is, since the first shield pattern SP1′ is electrically connected to the second conductive pattern DAT2′ that applies the first direct current voltage, and the third shield pattern SP3′ is electrically connected to the first shield pattern SP1′, the first direct current voltage may be applied to the first shield pattern SP1′ and the third shield pattern SP3′.

In an embodiment, the second shield pattern SP2′ may overlap with the first gate electrode GE1′ and the second gate electrode GE2′ in a plan view. That is, the first transistor TR1′ and the second transistor TR2′ may be disposed to overlap each other in a plan view, and the second shield pattern SP2′ may be disposed between the first transistor TR1′ and the second transistor TR2′. Accordingly, the second shield pattern SP2′ may prevent an electric signal of the first gate electrode GE1′ from affecting the second channel region CH2′ of the second transistor TR2′. As a result, the second shield pattern SP2′ may prevent or reduce a coupling phenomenon between the first transistor TR1′ and the second transistor TR2′.

In an embodiment, the second shield pattern SP2′ may be electrically connected to the first gate electrode GE1′ and the second gate electrode GE2′. Since the second gate electrode GE2′ and the second shield pattern SP2′ are electrically connected, the second shield pattern SP2′ may serve as a lower gate of the second transistor TR2′ to increase a carrier mobility of the second active layer ACT2′.

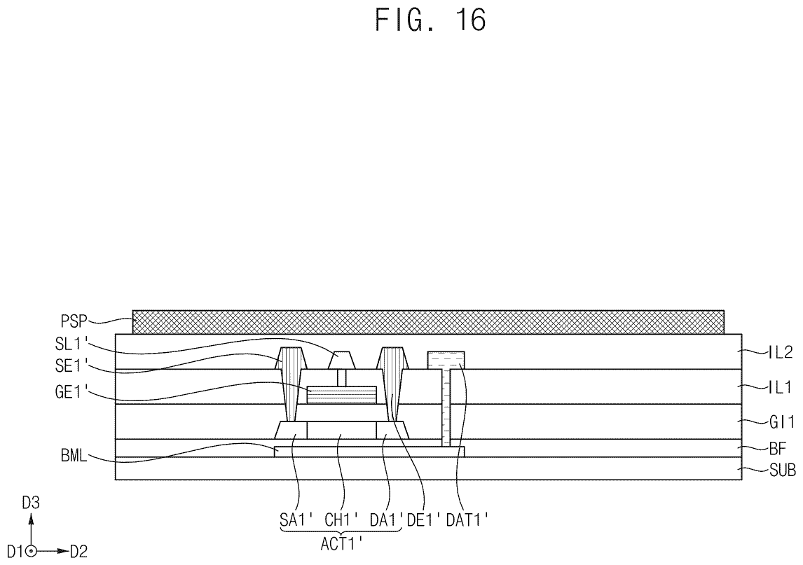

FIGS. 16, 17, 18, 19, and 20 are cross-sectional views showing a method of manufacturing the display device of FIG. 15, according to an embodiment. Specifically, FIGS. 16, 17, 18, 19, and 20, which are a manufacturing method of the display device DD′ of FIG. 14, illustrate subsequent views of the manufacturing method of FIGS. 5, 6, and 7. That is, FIGS. 5, 6, and 7 may be views showing a common manufacturing method of the display device DD of FIG. 3 and the display device DD′ of FIG. 14. Hereinafter, overlapping content may be omitted or simplified.

In an embodiment and referring to FIG. 16, the preliminary shield pattern PSP may be formed on the second insulating layer IL2, where the preliminary shield pattern PSP may be applied to an entire area on the second insulating layer IL2 with a constant thickness.

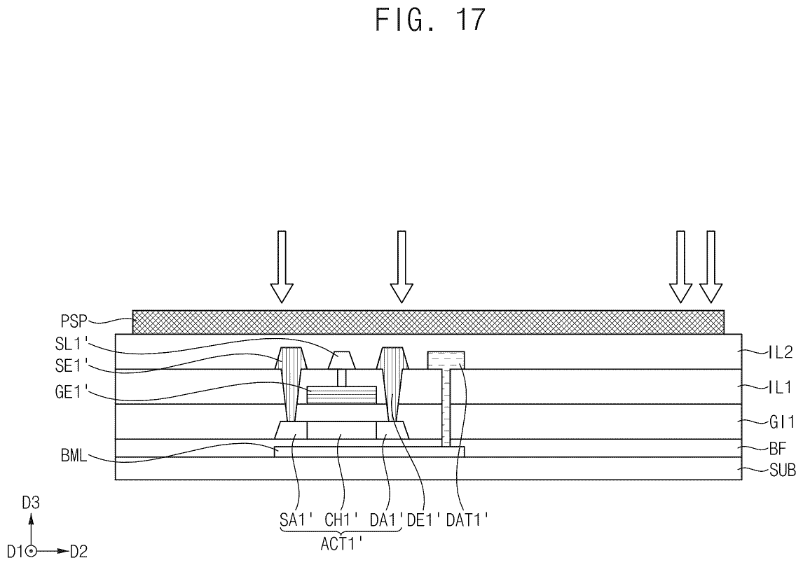

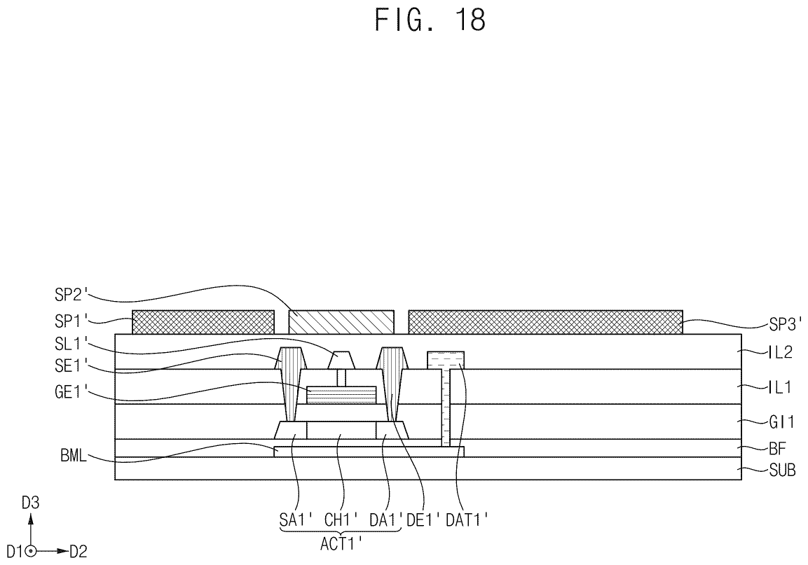

In an embodiment and referring further to FIGS. 17 and 18, the preliminary shield pattern PSP may be patterned to form a shield pattern SP′. Specifically, the preliminary shield pattern PSP may be patterned to form the first shield pattern SP1′, the second shield pattern SP2′, and the third shield pattern SP3′. For example, the second shield pattern SP2′ may be formed to overlap with the first gate electrode GE1′ of the first transistor TR1′ in a plan view. The first shield pattern SP1′ and the third shield pattern SP3′ may be formed not to overlap with the first gate electrode GE1′ in a plan view.

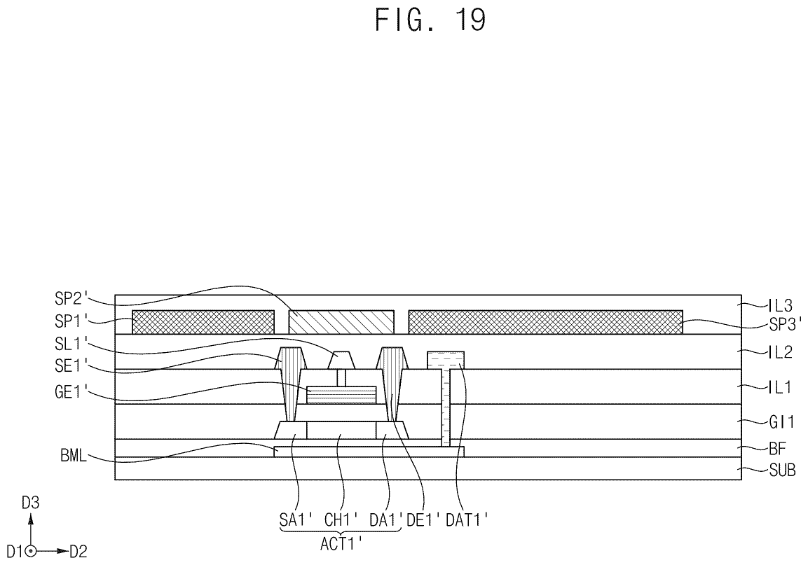

In an embodiment and referring further to FIG. 19, the third insulating layer IL3 covering the shield pattern SP′ may be formed on the second insulating layer IL2.

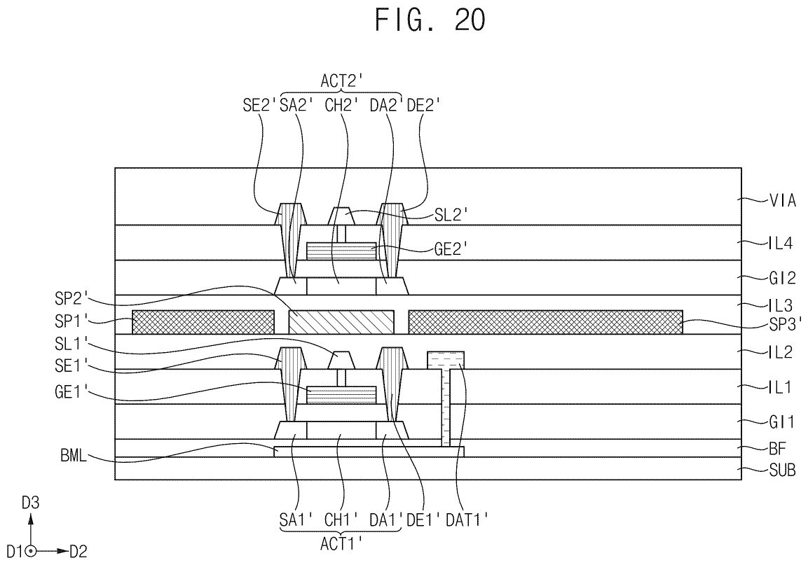

In an embodiment and referring further to FIG. 20, a second transistor TR2′ including the second active layer ACT2′ may be formed on the third insulating layer IL3. The second channel region CH2′ of the second active layer ACT2′ may be formed to overlap with the second shield pattern SP2′ in a plan view. Thereafter, the first gate electrode GE1′, the second shield pattern SP2′, and the second gate electrode GE2′ may be electrically connected.

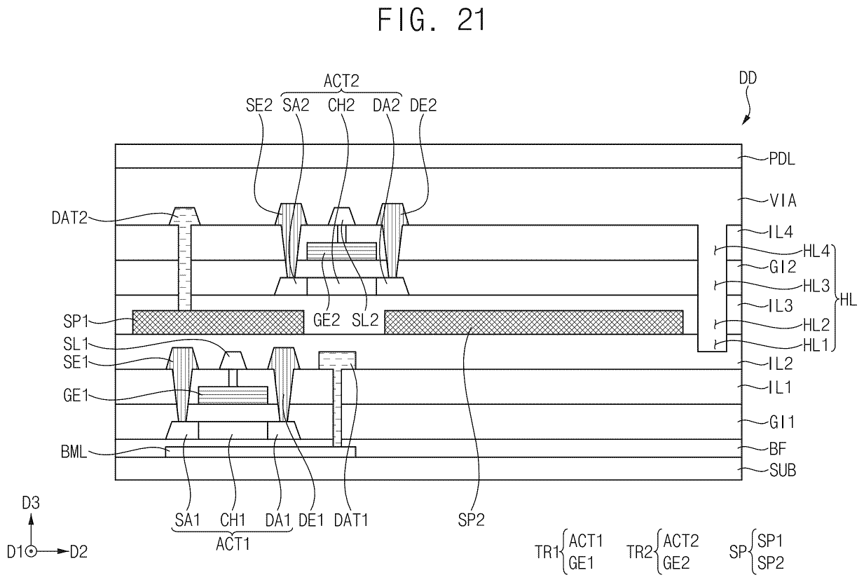

FIG. 21 is a cross-sectional view showing still another embodiment of the display device of FIG. 2. FIG. 21 may be substantially same as the embodiment of FIG. 3 except that holes HL are defined. Therefore, overlapping content may be omitted or simplified.

In an embodiment and referring to FIG. 21, holes HL may be defined in the display device DD. Specifically, the holes HL may include a first hole HL1 defined in a part of the second insulating layer IL2, a second hole HL2 defined in the third insulating layer IL3, a third hole HL3 defined in the second gate insulating layer GI2, and a fourth hole HL4 defined in the fourth insulating layer IL4. The holes HL may overlap in a plan view. That is, the second hole HL2 may extend from the first hole HL1 and penetrate the third insulating layer IL3. The third hole HL3 may extend from the second hole HL2 and penetrate the second gate insulating layer GI2. The fourth hole HL4 may extend from the third hole HL3 and penetrate the fourth insulating layer IL4. The holes HL may be filled with an insulating material. For example, as shown in FIG. 21, the holes HL may be filled with a material forming the via layer VIA.

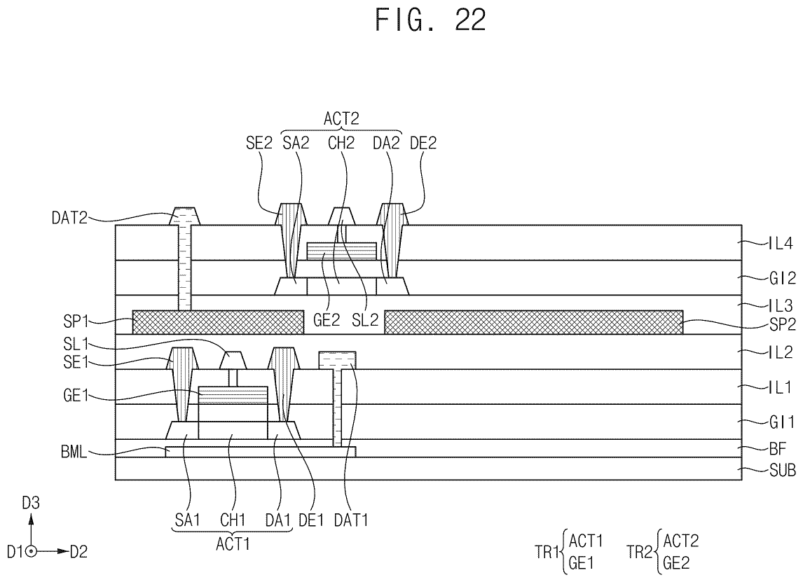

FIGS. 22, 23, and 24 are cross-sectional views showing a method of manufacturing the display device of FIG. 21, according to an embodiment.

In an embodiment and referring to FIG. 22 and FIG. 23, after the second transistor TR2 is formed, the holes HL may be formed. The first hole HL1 may be formed in a portion of the second insulating layer IL2, the second hole HL2 may be formed in the third insulating layer IL3, the third hole HL3 may be formed in the second gate insulating layer GI2, and the fourth hole HL4 may be formed in the fourth insulating layer IL4.

In an embodiment, at least one of the second insulating layer IL2, the third insulating layer IL3, the second gate insulating layer GI2, and the fourth insulating layer IL4 may include an organic material. When at least one of the second insulating layer IL2, the third insulating layer IL3, the second gate insulating layer GI2, and the fourth insulating layer IL4 is made of an organic material, the holes HL may become a space through which gas generated by the organic materials escapes during a manufacturing process of the display device (e.g., the display device DD of FIG. 21). That is, if the holes HL did not exist, a problem in flattening the display device (e.g., the display device DD of FIG. 21) could occur due to the gas, but by defining the holes HL, the gas may escape, thereby solving the problem in the manufacturing process.

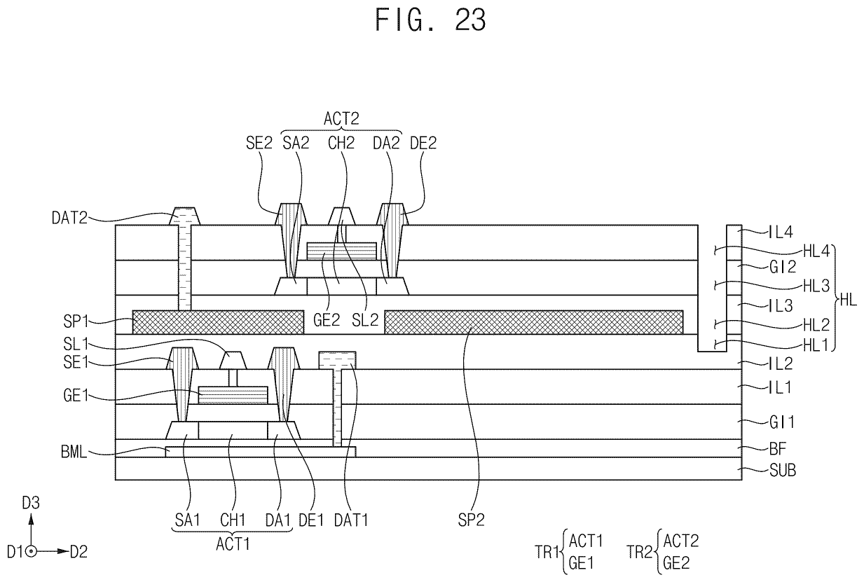

In an embodiment and referring further to FIG. 24, after all of the gas has escaped, the via layer VIA may be formed on the fourth insulating layer IL4, thereby filling all of empty spaces caused by the holes HL. That is, by forming the via layer VIA on the fourth insulating layer IL4, the holes HL may be filled with a same material as the via layer VIA.

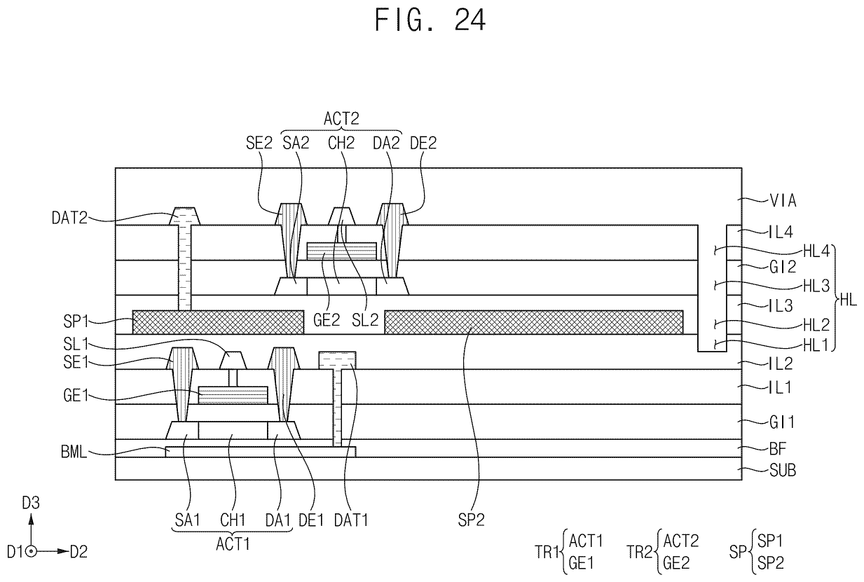

FIG. 25 is a cross-sectional view showing still another embodiment of the display device of FIG. 2. Specifically, FIG. 25 may be substantially the same as FIG. 14 except that the holes HL are defined, and therefore, overlapping content may be omitted or simplified.

In an embodiment and referring further to FIG. 25, the holes HL may be defined by penetrating the fourth insulating layer IL4, the second gate insulating layer GI2, the third insulating layer IL3, and the second insulating layer IL2. Each of the holes HL may be defined to overlap in a plan view.

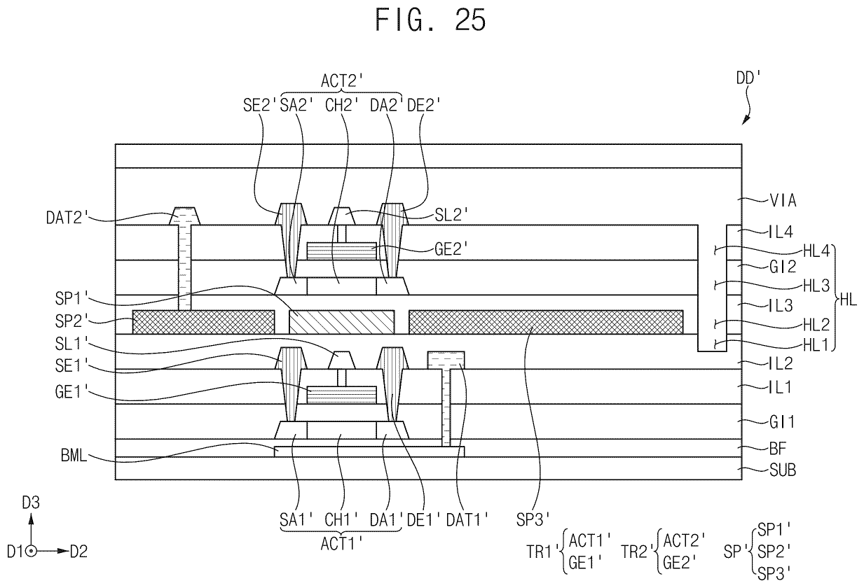

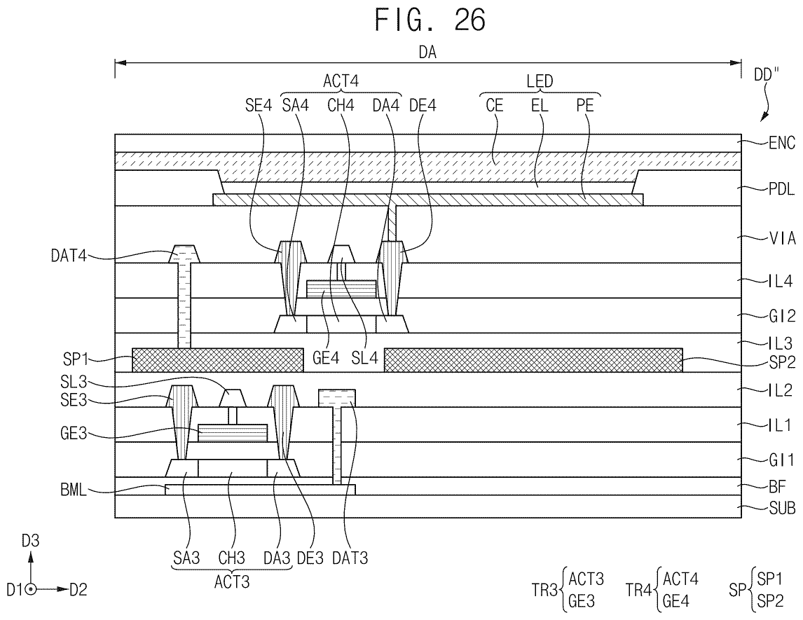

FIG. 26 is a cross-sectional view showing still another embodiment of the display device of FIG. 2. FIG. 27 is a cross-sectional view showing still yet another embodiment of the display device of FIG. 2.

Specifically, in an embodiment, the display device DD″ shown in FIG. 26 may have substantially the same laminated structure as the display device DD shown in FIG. 3 except for the light emitting diode LED. The display device DD′″ shown in FIG. 27 may have substantially the same laminated structure as the display device DD′ shown in FIG. 14 except for the arrangement of the light emitting diode LED. Therefore, overlapping content may be omitted or simplified.

In an embodiment and referring to FIGS. 1, 2, and 26, the display device DD″ may include the substrate SUB, the light shielding layer BML, the buffer layer BF, the third transistor TR3, the first and second gate insulating layers GI1, GI2, respectively, the first, second, third, and fourth insulating layers IL1, IL2, IL3, and IL4, respectively, the first conductive pattern DAT3, the shield pattern SP, the fourth transistor TR4, the second conductive pattern DAT4, the via layer VIA, the pixel defining layer PDL, and a light emitting diode LED. The light emitting diode LED may include a pixel electrode PE, an emitting layer EL, and a common electrode CE.

In an embodiment, the third transistor TR3 may include a third active layer ACT3, a third gate electrode GE3, a third source electrode SE3, and a third drain electrode DE3. The fourth transistor TR4 may include a fourth active layer A CT4, a fourth gate electrode GE4, a fourth source electrode SE4, and a fourth drain electrode DE4.

In an embodiment, he third active layer ACT3 may be disposed on the buffer layer BF. For example, the third active layer ACT3 may be disposed on a same layer as the first active layer (e.g., the first active layer ACT1 of FIG. 3). The third active layer ACT3 may define a third source region SA3, a third drain region DA3, and a third channel region CH3 located between the third source region SA3 and the third drain region DA3. The third active layer ACT3 may include an oxide semiconductor, a silicon semiconductor, an organic semiconductor, etc. The third layer ACT3 may have a structure in which two layers having different compositions are laminated.

In an embodiment, a third sensing line SL3 may be disposed in a same layer as the third source electrode SE3 and the third drain electrode DE3 and may apply the gate signal applied from the gate driver GIC to the third gate electrode GE3. The third sensing line SL3 may include a same material as the third source electrode SE3 and the third drain electrode DE3.

In an embodiment, the third conductive pattern DAT3 may be disposed on a same layer as the third source electrode SE3. However, the invention is not necessarily limited thereto, and in another embodiment, the third conductive pattern DAT3 may be disposed on an arbitrary layer disposed below the fourth transistor TR4. The third conductive pattern DAT3 may not overlap with the shield pattern SP in a plan view.

In an embodiment, the fourth active layer ACT4 may be disposed on the third insulating layer IL3. A fourth source region SA4, a fourth drain region DA4, and a fourth channel region CH4 located between the fourth source region SA4 and the fourth drain region DA4 may be defined in the fourth active layer ACT4.

In an embodiment, the fourth active layer ACT4 may include a same material as the third active layer ACT3. The fourth active layer ACT4 may have a structure in which two layers having different compositions are laminated.

However, the invention is not necessarily limited thereto, and in another embodiment, one of the third transistor TR3 and/or the fourth transistor TR4 of the display device DD″ may be omitted. That is, only the third transistor TR3 may be included, or only the fourth transistor TR4 may be included.

In an embodiment, the pixel electrode PE may be disposed on the via layer VIA and may include a conductive material. The pixel electrode PE may be electrically connected to the fourth drain electrode DE4. That is, the pixel electrode PE may be electrically connected to the fourth transistor TR4.

In an embodiment, the light emitting layer EL may be disposed on the pixel electrode PE. Specifically, the light emitting layer EL may be disposed within an opening defined by the pixel defining layer PDL. That is, the light emitting layer EL may be surrounded by the pixel defining layer PDL and may include at least one of an organic light emitting material and/or a quantum dot. However, the invention is not necessarily limited thereto.

In an embodiment, the common electrode CE may be disposed on the light emitting layer EL. The common electrode CE may also be disposed on the pixel defining layer PDL. That is, the common electrode CE may be disposed continuously on the light emitting layer EL and the pixel defining film PDL. The common electrode CE may include a conductive material. The light emitting layer EL may emit light based on a voltage difference between the pixel electrode PE and the common electrode CE.

In an embodiment and referring further to FIG. 1, FIG. 2, and FIG. 27, the display device DD′″ may include a substrate SUB, a light shielding layer BM L, a buffer layer BF, a third transistor TR3′, first and second gate insulating layers GI1, GI2, first, second, third, and fourth insulating layers IL1, IL2, IL3, and IL4, a first conductive pattern DAT3′, a shield pattern SP, a fourth transistor TR4′, a second conductive pattern DAT4′, a via layer VIA, a pixel defining layer PDL, and a light emitting diode LED.

In an embodiment, the third transistor TR3′ may include a third active layer ACT3′, a third gate electrode GE3′, a third source electrode SE3′, and a third drain electrode DE3′. The fourth transistor TR4′ may include a fourth active layer ACT4′, a fourth gate electrode GE4′, a fourth source electrode SE4′, and a fourth drain electrode DE4′.

In an embodiment, the third active layer ACT3′ may be disposed on the buffer layer BF. For example, the third active layer ACT3′ may be disposed on a same layer as the first active layer (e.g., the first active layer ACT1′ of FIG. 14). The third active layer ACT3′ may define a third source region SA3′, a third drain region DA3′, and a third channel region CH3′ located between the third source region SA3′ and the third drain region DA3′. The third active layer ACT3′ may include an oxide semiconductor, a silicon semiconductor, an organic semiconductor, etc. The third layer ACT3′ may have a structure in which two layers with different compositions are laminated.

In an embodiment, the third sensing line SL3′ may be disposed in a same layer as the third source electrode SE3′ and the third drain electrode DE3′. The third sensing line SL3′ may apply the gate signal applied from the gate driver GIC to the third gate electrode GE3′. The third sensing line SL3 may include a same material as the third source electrode SE3′ and the third drain electrode DE3′.

In an embodiment, the third conductive pattern DAT3′ may be disposed in a same layer as the third source electrode SE3′. However, the invention is not necessarily limited thereto, and in another embodiment, the third conductive pattern DAT3′ may be disposed in an arbitrary layer located below the fourth transistor TR4′. The third conductive pattern DAT3′ may not overlap with the shield pattern SP′ in a plan view.

In an embodiment, the fourth active layer ACT4′ may be disposed on the third insulating layer IL3. A fourth source region SA4′, a fourth drain region DA4′, and a fourth channel region CH4′ located between the fourth source region SA4′ and the fourth drain region DA4′ may be defined in the fourth active layer ACT4′. The fourth active layer ACT4′ may include a same material as the third active layer ACT3′. The fourth active layer ACT4′ may have a structure in which two layers having different compositions are laminated.

However, the invention is not necessarily limited thereto, and in another embodiment, one of the third transistor TR3′ and/or the fourth transistor TR4′ of the display device DD′″ may be omitted. That is, only the third transistor TR3′ may be included, or only the fourth transistor TR4′ may be included.

As a result, in an embodiment, a description referring to FIGS. 26 and 27 indicates that the stacked structure of the display device DD of FIG. 3 and the display device DD′ of FIG. 14 may be equally applied to the pixel circuit of the display area DA. That is, by vertically stacking the transistors, not only an area in a plan view of the peripheral area SA may be reduced, but also an area of the pixel circuit disposed in the display area DA may be reduced, so that a resolution of the display area DA may be increased.

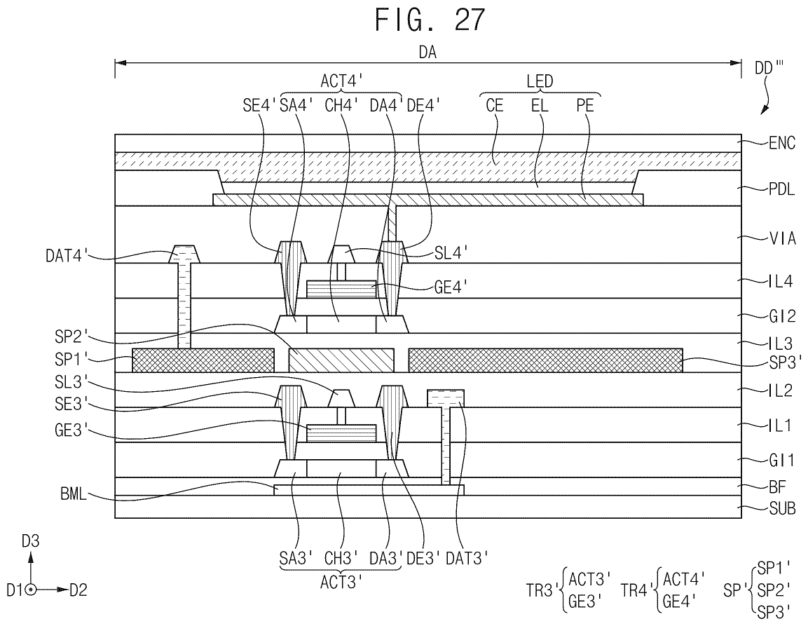

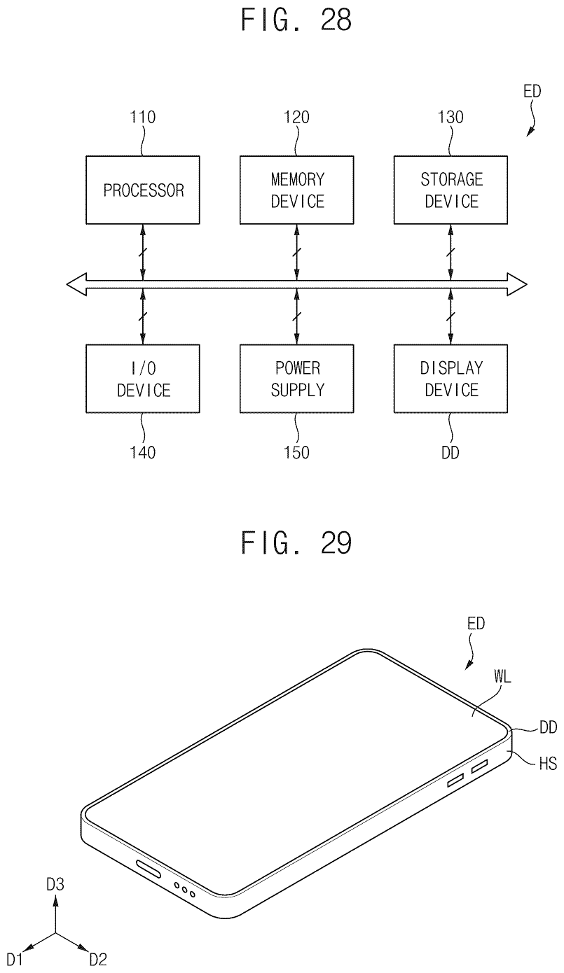

FIG. 28 is a block-diagram showing an embodiment of an electronic device including the display device of FIG. 1. FIG. 29 is a perspective view showing an embodiment of the electronic device of FIG. 28.

In an embodiment and referring to FIGS. 28 and 29, an electronic device ED may include a processor 110, a memory device 120, a storage device 130, an input/output device 140, a power supply 150, and the display device DD. The display device DD included in the electronic device ED may be the display device DD of FIG. 1. In addition, the electronic device ED may further include several ports capable of communicating with a video card, a sound card, a memory card, a USB device, etc., or communicating with other systems.

In an embodiment, the processor 110 may perform specific calculations or tasks. In an embodiment, the processor 110 may be a microprocessor, a central processing unit, an application processor, etc. The processor 110 may be connected to other components through an address bus, a control bus, a data bus, etc. In an embodiment, the processor 110 may also be connected to an expansion bus, such as a Peripheral Component Interconnect (PCI) bus. The processor 110 may output data control signals and image data to the timing controller.

In an embodiment, the memory device 120 may store data necessary for an operation of the electronic device ED. For example, the memory device 120 may include nonvolatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), a ferroelectric random access memory (FRAM) device, and/or a volatile memory device such as a dynamic random access memory (DRA M) device, a static random access memory (SRAM) device, a mobile DRAM device, and the like.

In an embodiment, the storage device 130 may include a solid state drive (SSD), a hard disk drive (HDD), a CD-ROM, etc. The input/output device 140 may include an input means such as a keyboard, a keypad, a touchpad, a touchscreen, a mouse, etc., and an output means such as a speaker, a printer, etc. In an embodiment, the display device DD may be included in the input/output device. The power supply 150 may supply power required for the operation of the electronic device ED. The display device may be connected to other components through the buses or other communication links.

In an embodiment and referring further to FIG. 29, the electronic device ED may be implemented as a smartphone. The electronic device ED may include a window layer WL, a display device DD, and a housing HS.

In an embodiment, the window layer WL may cover the display device DD. For example, the window layer WL may be disposed on the display area (e.g., a display area DA of FIG. 1) of the display device DD to cover the display device DD. Accordingly, the window layer WL may protect the display area of the display device DD where the image is displayed.

In an embodiment, the housing HS may surround the display device DD. For example, the display device DD may be accommodated in the housing HS. The housing HS may cover side and bottom of the display device DD. Accordingly, the housing HS may supplement a rigidity of the display device DD and protect the display device DD from external impact.

In an embodiment, a functional module such as a camera module or a sensor module may be accommodated in the housing HS. Accordingly, the functional module may be electrically connected to the display device DD and may perform a specific function. However, type or arrangement of the functional module according to the invention is not necessarily limited thereto.

However, this is exemplary, and the electronic device ED, according to embodiments, is not necessarily limited thereto. For example, the electronic device ED may be implemented as a mobile phone, a video phone, a smart pad, a smart watch, a tablet PC, a vehicle display, a computer monitor, a notebook computer, a head-mounted display device, etc. In addition, the electronic device ED may be a television, a monitor, a notebook computer, or a tablet. In addition, the electronic device ED may be a car.

The foregoing is illustrative of the invention and is not to be construed as limiting thereof. Although a few embodiments have been described, those skilled in the art will readily appreciate that many modifications are possible without materially departing from the novel teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the invention, as well as other embodiments, are intended to be included within the scope of the invention. Moreover, the invention or parts of the invention may be combined in whole or in part without departing from the scope of the invention.

What is claimed is:

1. A display device comprising:
a substrate including a display area, and a peripheral area surrounding the display area;
a first transistor disposed in the peripheral area and including
a first active layer having a first channel region; and
a first gate electrode,
a first insulating layer disposed on the first transistor;
a first shield pattern disposed on the first insulating layer, to which a direct current voltage is applied;
a second insulating layer covering the first shield pattern; and
a second transistor directly disposed on the second insulating layer and including
a second active layer having a second channel region spaced apart from the first shield pattern in a plan view; and
a second gate electrode.

2. The display device of claim 1, wherein the first gate electrode and the second gate electrode are spaced apart from each other in a plan view.

3. The display device of claim 2, further comprising
a conductive pattern disposed below the second transistor, wherein the conductive pattern does not overlap with the first shield pattern in a plan view, and
wherein the conductive pattern overlaps with the second channel region of the second transistor in a plan view.

4. The display device of claim 3, wherein the conductive pattern is disposed on a same layer as a source electrode of the first transistor.

5. The display device of claim 3, wherein the conductive pattern is electrically connected to a source electrode of the second transistor or the second gate electrode.

6. The display device of claim 2, further comprising,
a second shield pattern disposed to be spaced apart from the second channel region of the second transistor in a plan view, and
wherein the second shield pattern is disposed on a same layer as the first shield pattern and is spaced apart from the first shield pattern.

7. The display device of claim 2, wherein the first shield pattern overlaps the first gate electrode in a plan view.

8. The display device of claim 1, further comprising,
a second shield pattern spaced apart from the first shield pattern and including a same material as the first shield pattern,
wherein the second shield pattern overlaps the second channel region of the second transistor in a plan view.

9. The display device of claim 8,
wherein a first direct current voltage is applied to the first shield pattern, and
a second direct current voltage different from the first direct current voltage is applied to the second shield pattern.

10. The display device of claim 8, wherein the second shield pattern is electrically connected to the first gate electrode and the second gate electrode.

11. The display device of claim 8, wherein the first gate electrode and the second gate electrode overlap in a plan view.

12. The display device of claim 1, further comprising:
a third transistor disposed in the display area and including a third active layer disposed on a same layer as the first active layer of the first transistor; and
a light emitting diode electrically connected to the third transistor.

13. The display device of claim 1, wherein each of the first active layer and the second active layer includes an oxide semiconductor.

14. The display device of claim 1, wherein a mobility of the second active layer is greater than a mobility of the first active layer.

15. The display device of claim 1, wherein each of the first insulating layer and the second insulating layer is an organic layer.

16. The display device of claim 15, further comprising:
a first hole defined in the first insulating layer; and
a second hole defined in the second insulating layer, wherein the second hole extends from the first hole, and penetrates the second insulating layer, and
wherein the first hole and the second hole are filled with an insulating material.

17. The display device of claim 1, wherein each of the first active layer and the second active layer is doped with an n-type material.

18. A method of manufacturing a display device comprising:
forming a first transistor including a first active layer and a first gate electrode on a substrate;
forming a first insulating layer on the first transistor;
forming a conductive preliminary shield pattern on the first insulating layer;
patterning the preliminary shield pattern to form a first shield pattern that applies a direct current voltage;
forming a second insulating layer covering the first shield pattern; and
forming a second transistor on the second insulating layer,
wherein the second transistor includes
a second active layer including a second channel region that does not overlap with the first shield pattern in a plan view; and
a second gate electrode disposed directly on the second insulating layer.

19. The method of claim 18, further comprising:
wherein after forming the second transistor,
forming a first hole in the first insulating layer and forming a second hole extending from the first hole in the second insulating layer; and
filling the first hole and the second hole with an insulating material.

20. An electronic device comprising:
a housing; and
a display device stored in the housing and that displays an image,
wherein the display device includes:
a substrate including a display area and a peripheral area surrounding the display area;
a first transistor disposed in the peripheral area and including
a first active layer having a first channel region; and
a first gate electrode,
a first insulating layer disposed on the first transistor;
a first shield pattern disposed on the first insulating layer and to which a direct current voltage is applied;
a second insulating layer covering the first shield pattern; and
a second transistor directly disposed on the second insulating layer and including
a second active layer having a second channel region spaced apart from the first shield pattern in a plan view; and
a second gate electrode.
